(19) United States
(12) Patent Application Publication
(10) Pub. No.: US 2002/0124204 A1
(43) Pub. Date: Sep. 5, 2002

(54) Guarantee of context synchronization in a system configured with control redundancy

(76) Inventors: Ling-Zhong Liu, Ottawa (CA); Peifang Zhou, Kanata (CA)

Correspondence Address: MARKS & CLERK, P.O. BOX 957, STATION B, OTTAWA, ON, K1P 5S7, CA

(21) Appl. No.: 10/085,084

(22) Filed: Mar. 1, 2002

Related U.S. Application Data
(60) Provisional application No. 60/272,447, filed on Mar. 2, 2001.

(51) Int. Cl. G01R 31/08; G08C 15/00; H04L 12/26; G06F 11/00; H04J 1/16; H04L 1/00; H03K 19/003; H05K 10/00; H02H 3/05; H04J 3/14; H04B 1/74; H04L 1/22

(52) U.S. Cl. 714/11; 370/216

(57) ABSTRACT

In a system configured with control redundancy, there are two control elements: an active control complex and an inactive control complex. An increased level of fault tolerance can be achieved when switching the activity state between complexes in the event of a critical software or hardware failure. The present invention relates to system redundancy and introduces a new method to ensure that system context is always synchronized across a switch-over process.

This invention claims the benefit of U.S. Provisional Application No. 60/272,447 filed Mar. 2, 2001.

### FIELD OF THE INVENTION

This invention relates to system redundancy, and more particularly to imposed synchronization of system contexts in a redundantly controlled system.

### BACKGROUND

There are numerous applications, including digital communication systems, in which redundancy is desired or, in fact, mandatory. If, for example, a particular network element is responsible for implementing a critical function, it is common to employ a second, or backup element, to serve as a redundant element. In this manner, if for any reason, the primary element goes out of service, the second or backup element can assume control.

To ensure that the backup element is able to maintain the same system functionality as the primary element, they both must always have the same information or state.

In such a system, there will be two control elements identified herein as an active control complex and an inactive control complex. In the event of critical software or hardware faults, an increased level of fault tolerance can be achieved by switching the activity state of the two control complexes. Typically, there are a number of processes running on the active control complex. It is assumed that for any process running on the active control complex, there is an identical process running on the inactive control complex. A particular requirement for implementing control redundancy is that the context for some, if not all, processes has to be synchronized before the activity is switched from the active control complex to the inactive control complex. In general terms, the knowledge retained by the active control complex and the inactive control complex must be at the same level before the activity state is switched; otherwise, the system in consideration cannot provide seamless services in the event of an activity switch.

By way of example of the foregoing, consider the following simplified scenario. Assume, as shown in FIG. 1, that one process is running on the active control complex A and an identical process is running on the inactive control complex B using the same algorithm. Further assume that the contexts of both processes are also identical and called context or state C1 in FIG. 1. Assume now that an external stimulus (ES) that may be an event or a message, is received at complex A, and that this ES transitions the process context into a second context or state C2 on the active control complex A. At this time, the process context on the inactive complex B is still at the initial state C1. Under normal circumstances, the active control complex A will pass the new state C2 to the inactive control complex B. If, however, a catastrophic event occurs on the active control complex A which results in the active control complex A going out of service before the transfer of the new context C2 to the inactive control complex B is complete, the newly activated control complex B will start from either the old state or context C1 or a corrupted context due to an incomplete transfer.

For the sake of this discussion, it is assumed that in a distributed system a naming service guarantees that the newly activated process receives any new stimulus only after the failure of the old process. If the process restarts from the old context C1, the effect of the external stimulus would be lost. If the process starts from a corrupted context a crash is likely to occur. Either way, the process on the newly activated control complex would not have the same capability to maintain the same level of services had the activity not been switched. The invention uses a naming service to find the application that is either the producer or the manager of the event. A naming service can be described, in one particular instance, as a storage database of application names and their locations. The naming service enables network components to connect together without regard for the specific physical locations or configurations of the network.

Accordingly, there is a need for a mechanism to ensure that the contexts for the two identical processes on the active and inactive control complexes are synchronized at all times.

### SUMMARY OF THE INVENTION

The present invention relates to system redundancy and introduces a new method to ensure that system context is always synchronized across a switch-over process.

Therefore in accordance with a first aspect of the invention there is provided a method of achieving context synchronization in a system configured with control redundancy, the method comprising: providing means for a first control element to process a new context and to distribute the new context to a second control element; and providing means at the second control element to maintain synchronization of the new context with the first control element.

In accordance with a second broad aspect of the invention there is provided a system for achieving context synchronization in a system configured with control redundancy comprising: means for a first control element to process a new context and to distribute the new context to a second control element; and means at the second control element to maintain synchronization of the new context with the first control element.

More specifically the invention provides an Atomic Redundancy Synchronization Transaction (ARST) device for guaranteeing context synchronization between two identical processes on an active control complex and an inactive control complex: the ARST, comprising: means in the active control complex to receive an external stimulus message and to calculate a new context in response thereto; means in the active control complex to transfer the new context to the inactive complex and to transition to the new context; means in the inactive control complex to transition to the new context in synchronization with the transition to the new context in the active control complex; and means in the active control complex to acknowledge receipt of the external stimulus message.

In a preferred embodiment of this aspect of the invention a naming service enables network components to connect together regardless of physical location or network configuration.

### BRIEF DESCRIPTION OF THE DRAWINGS

The invention will now be described in greater detail with reference to the attached drawings wherein:

FIG. 1 shows a system according to the prior art without context synchronization of the present invention;

FIG. 2 shows the context synchronization according to the present invention.

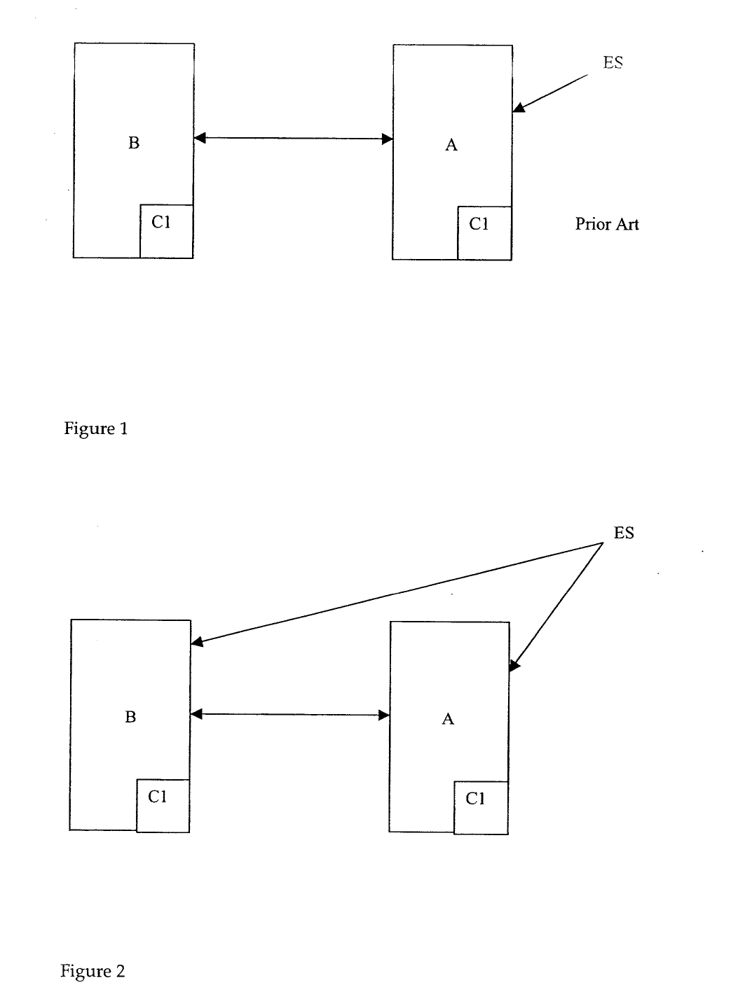

### DETAILED DESCRIPTION OF THE INVENTION

The essence of the present invention is illustrated in FIG. 2. In this discussion a mechanism called Atomic Redundancy Synchronization Transaction (ARST) is introduced. The ARST is introduced to guarantee the context synchronization between two identical processes on the active and inactive control complexes. In FIG. 2, assume that the contexts of the two identical processes on the active A and inactive B control complexes are synchronized, and the context is denoted as C1. After an external stimulus ES is received, the process on the active control complex calculates the new context C2 into which it will transition. The active complex A then initiates the transfer of context C2 to the inactive control complex B. Upon successful transfer, both processes will transition into the new context C2. The process on the active control complex will acknowledge receipt of the external stimulus ES. Under the ARST operation, the external stimulus ES source continues to send the ES message periodically until an acknowledgement is received. In this application, the calculation of the new context, its complete transfer from active control complex to inactive control complex, the transition of the two complexes to the new context, and the acknowledgement of the external stimulus ES is an ARST operation.

To understand the successful operation of an ARST, consider an example of the failure of the active control complex during a transfer to a new context. An ES will cause the active control complex A to calculate a new context C2. Control complex A begins to transfer the new context C2 to the inactive control complex B. Before the transfer is complete, control complex A fails. However, the effect of the ES is not lost due to the ARST operation. Because the ES source continues to send the ES message periodically until an acknowledgement is received, control complex B can still receive the ES due to the aforementioned naming service, calculate a new context C2, transition to the new context, and send an acknowledgment to the ES source, thus completing the ARST operation.

Therefore, the present invention uses the ARST operation to guarantee that the contexts of the active and inactive control complexes are always synchronized. Even in the event of a failure of the active control complex, midway through the transition to a new context, the system does not fail or operate at a lower capability because of the successful operation of the ARST.

Although FIG. 2 shows control complexes A and B in close proximity, it is to be understood that they may be connected to a common network element or may be distributed throughout a network.

Although particular embodiments of the invention have been described and illustrated it will be apparent to one skilled in the art that numerous changes can be made to the basic concept without departing from the basic concepts. It is to be understood that such changes will fall within the full scope of the invention as defined in the appended claims.

We claim:

1. A method of achieving context synchronization in a system configured with control redundancy comprising:
providing means for a first control element to process a new context and to distribute the new context to a second control element; and
providing means at said second control element to maintain synchronization of said new context with said first control element.

2. The method as defined in claim 1 wherein processing of a new context is initiated by an external stimulus message.

3. The method as defined in claim 2 wherein said first control element is an active control complex and said second control element is an inactive control complex.

4. The method as defined in claim 3 wherein said active control complex calculates a new context and transfers the new context to said inactive control complex.

5. The method as defined in claim 4 wherein said active control complex transitions into said new context after successfully completing the transfer of said new context to said inactive control complex.

6. The method as defined in claim 5 wherein upon transition of said inactive complex to said new context said active control complex will acknowledge receipt of said external stimulus.

7. The method as defined in claim 6 wherein external stimulus messages will continue to be sent periodically until an acknowledgement has been received.

8. The method as defined in claim 7 wherein said inactive control context assumes control upon a failure of said active control context.

9. A system for achieving context synchronization in a system configured with control redundancy comprising:
means for a first control element to process a new context and to distribute the new context to a second control element; and
means at said second control element to maintain synchronization of said new context with said first control element.

10. An Atomic Redundancy Synchronization Transaction (ARST) device for guaranteeing context synchronization between two identical processes on an active control complex and an inactive control complex comprising:
means in said active control complex to receive an external stimulus message and to calculate a new context in response thereto;
means in said active control complex to transfer said new context to said inactive control context and to transition to said new context;
means in said inactive control complex to transition to said new context in synchronization with said new context in said active control complex; and
means in said active control complex to acknowledge receipt of said external stimulus message.

11. The ARST as defined in claim 10 wherein a naming service is used to enable said active control complex and said inactive control complex to be connected regardless of physical location or network configuration.

12. The ARST as defined in claim 11 wherein said naming service is a storage database of control process names and locations.

13. The ARST as defined in claim 12 wherein said naming service enables the external stimulus message to be sent to both the active control complex and the inactive control complex.

14. The ARST as defined in claim 13 wherein said external stimulus message is continually sent periodically until an acknowledgement has been received.

15. The ARST as defined in claim 14 wherein if said active control context fails to acknowledge said external stimulus message said inactive control context, upon receipt of said message, calculates a new context, transitions to said new process and becomes the active control complex.
